(19) United States
(12) Patent Application Publication
(10) Pub. No.: US 2008/0213990 A1
(43) Pub. Date: Sep. 4, 2008

(54) METHOD FOR FORMING GATE ELECTRODE IN SEMICONDUCTOR DEVICE

(75) Inventors: Sang-Rok OH, Ichon-shi (KR); Jae-Seon YU, Ichon-shi (KR)

Correspondence Address: LOWE HAUPTMAN HAM & BERNER, LLP, 1700 DIAGONAL ROAD, SUITE 300, ALEXANDRIA, VA, 22314, US

(73) Assignee: HYNIX SEMICONDUCTOR INC., Ichon-shi (KR)

(21) Appl. No.: 11/964,332

(22) Filed: Dec. 26, 2007

(30) Foreign Application Priority Data
Jan. 3, 2007 (KR) 10-2007-0000403

(51) Int. Cl. H01L 21/3205

(52) U.S. Cl. 438/595; 257/E21.294

(57) ABSTRACT

A method for forming a gate electrode in a semiconductor device includes providing a substrate, forming a gate insulation layer over the substrate, forming first and second conductive layers over the gate insulation layer, forming a hard mask pattern over the second conductive layer, etching the second conductive layer using the hard mask pattern as an etch mask, performing an oxidation process to form an anti-oxidation layer on a sidewall of the etched second conductive layer, and etching the first conductive layer using the hard mask as an etch mask.

### CROSS-REFERENCE TO RELATED APPLICATIONS

The present invention claims priority of Korean patent application number 2007-0000403, filed on Jan. 3, 2007, which is incorporated by reference in its entirety.

### BACKGROUND OF THE INVENTION

The present invention relates to a method for fabricating a semiconductor device, and more particularly, to a method for fabricating a gate electrode in the semiconductor device.

Recently, tungsten (W) has been used for forming a gate electrode of semiconductor devices. That is, the semiconductor devices generally employ a gate electrode having a polysilicon layer, a tungsten layer and a gate hard mask layer which are formed sequentially over a gate insulation layer.

However, when forming the gate electrode using the tungsten layer, a top surface of the tungsten layer can be oxidized during the subsequent processes performed in an oxygen (O₂) atmosphere, thereby forming an abnormal oxide layer on a sidewall of the tungsten layer.

As a solution to the above problem, a capping layer has been used to prevent an abnormal oxidation of the tungsten layer. That is, after the tungsten layer is etched, the capping layer is formed on the sidewall of the tungsten layer to prevent the sidewall of the tungsten layer from being oxidized.

FIGS. 1A to 1E are cross-sectional views of a typical method for forming a gate electrode employing a capping layer.

Referring to FIG. 1A, a gate insulation layer 101, a polysilicon layer 102, a tungsten layer 103, and a hard mask layer 104 are sequentially formed over a substrate 100.

Referring to FIG. 1B, portions of the hard mask layer 104 and the tungsten layer 103 are etched to form a hard mask pattern 104A and a tungsten pattern 103A.

Referring to FIG. 1C, a capping nitride layer 105 is deposited on a surface of a resultant structure including the hard mask pattern 104A and the tungsten pattern 103A.

Referring to FIG. 1D, the capping nitride layer 105 is etched to form capping spacers 105A on sidewalls of the hard mask pattern 104A and the tungsten pattern 103A.

Referring to 1E, the polysilicon layer 102 and the gate insulation layer 101 are etched using the capping spacers 105A as an etch barrier. Thus, a gate electrode including a stack structure of a gate insulation pattern 101A, a polysilicon pattern 102A, a tungsten pattern 103A, and a hard mask pattern 104A is formed.

However, in the typical process for forming the gate electrode, a spacer-shaped passivation layer including the capping nitride layer is deposited on the sidewalls of the tungsten pattern 103A. Thus, it is difficult to adjust a profile and a critical dimension (CD) of the tungsten pattern 103A. In other words, as shown in FIG. 1E, the CD of the tungsten pattern 103A is smaller than that of the underlying silicon pattern 102A.

Also, the capping layer formed on the sidewall of the tungsten pattern 103A increases resistance of the tungsten layer, thereby increasing the entire resistance of the gate electrode. That is, a CD of the gate electrode is identical to that of the underlying polysilicon pattern 102A. However, the tungsten pattern 103A has a CD decreased by a thickness of the capping layer formed on both sidewalls of the tungsten pattern 103A. Thus, a surface area of the tungsten pattern 103A becomes smaller than that of the polysilicon pattern 102A. As a result, in spite of the tungsten layer's excellent characteristics of low resistance, the total resistance of the gate electrode increases than expected.

Also, the capping layer decreases a gap between the gate electrodes, thereby causing a process failure during a subsequent self-aligned contact (SAC) process. Furthermore, after etching the tungsten layer, the capping layer is formed separately and then, the polysilicon layer is etched. Therefore, the number of processes increases, thereby increasing production costs.

### SUMMARY OF THE INVENTION

The present invention is directed to providing a method for forming a gate electrode in a semiconductor device. The method omits a process step for forming a separate capping layer to prevent abnormal oxidation of a tungsten layer in forming a gate electrode in a semiconductor device. Therefore, the process for forming the gate electrode is simplified and a device failure caused by the capping layer is also prevented.

In accordance with an aspect of the present invention, there is provided a method for forming a gate electrode in a semiconductor device. The method includes providing a substrate, forming a gate insulation layer over the substrate, forming first and second conductive layers over the gate insulation layer, forming a hard mask pattern over the second conductive layer, etching the second conductive layer using the hard mask pattern as an etch mask, performing an oxidation process to form an anti-oxidation layer on a sidewall of the etched second conductive layer, and etching the first conductive layer using the hard mask as an etch mask.

### BRIEF DESCRIPTION OF THE DRAWINGS

FIGS. 1A to 1E are cross-sectional views of a typical method for forming a gate electrode.

FIGS. 2A to 2F are cross-sectional views of a method for fabricating a semiconductor device in accordance with an embodiment the present invention.

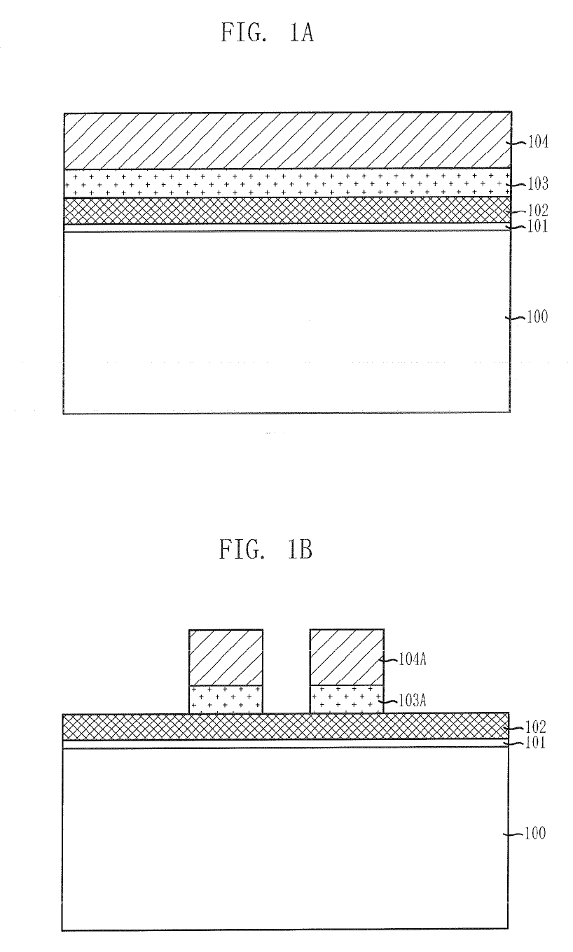

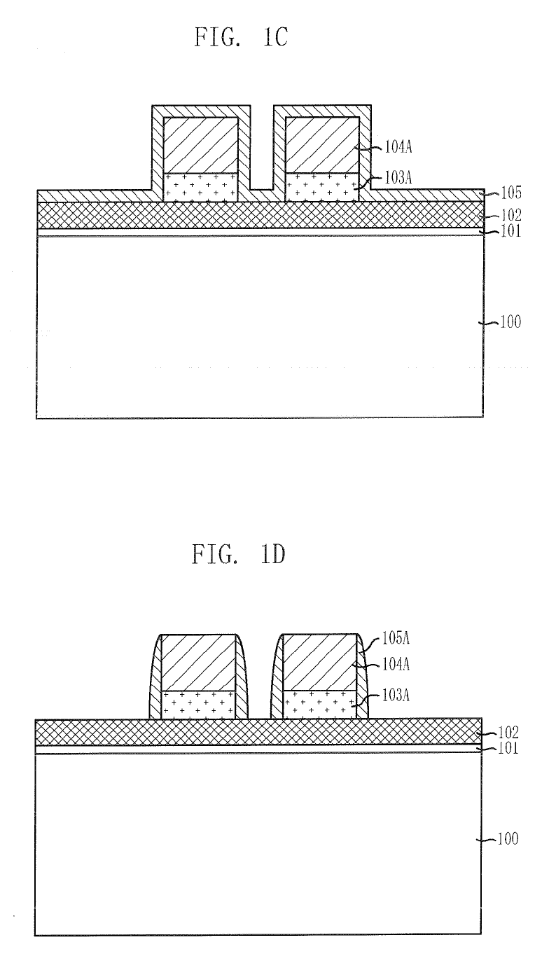

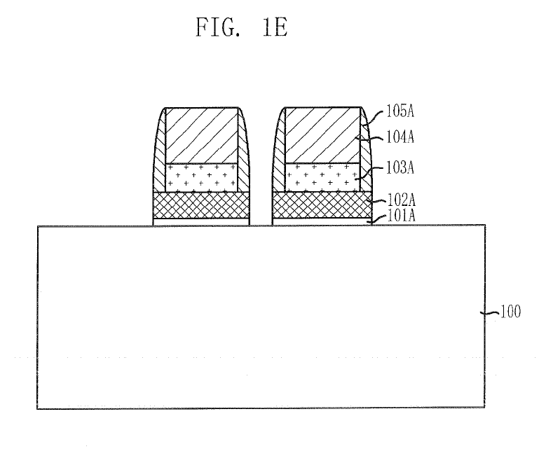

### DESCRIPTION OF SPECIFIC EMBODIMENTS

Embodiments of the present invention relate to a method for forming a gate electrode in a semiconductor device.

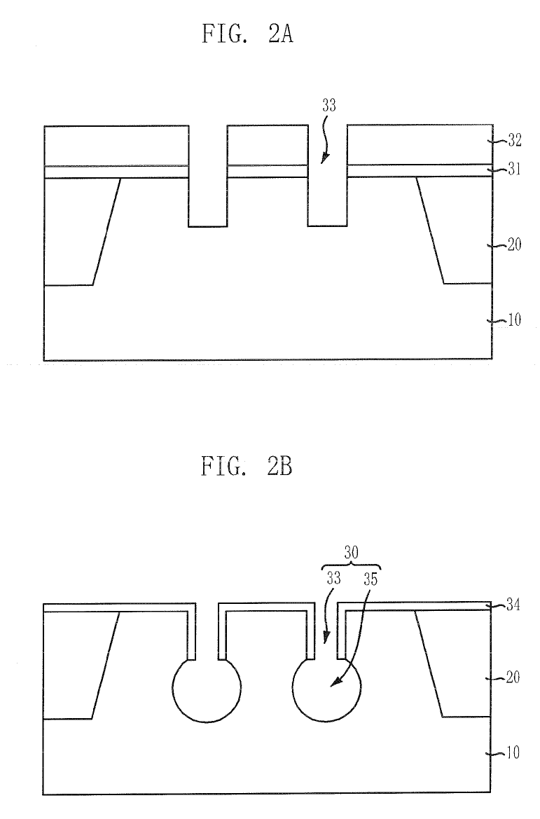

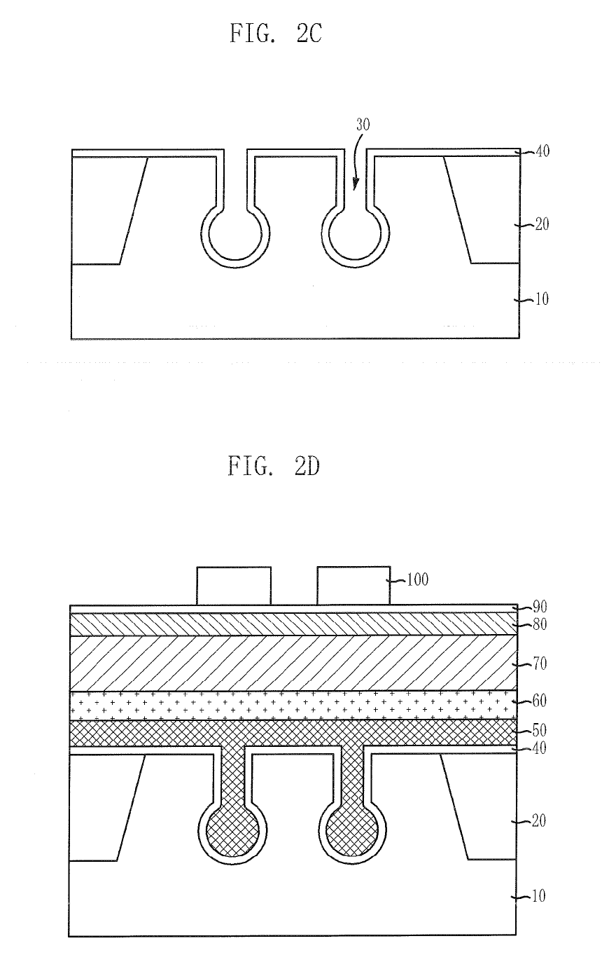

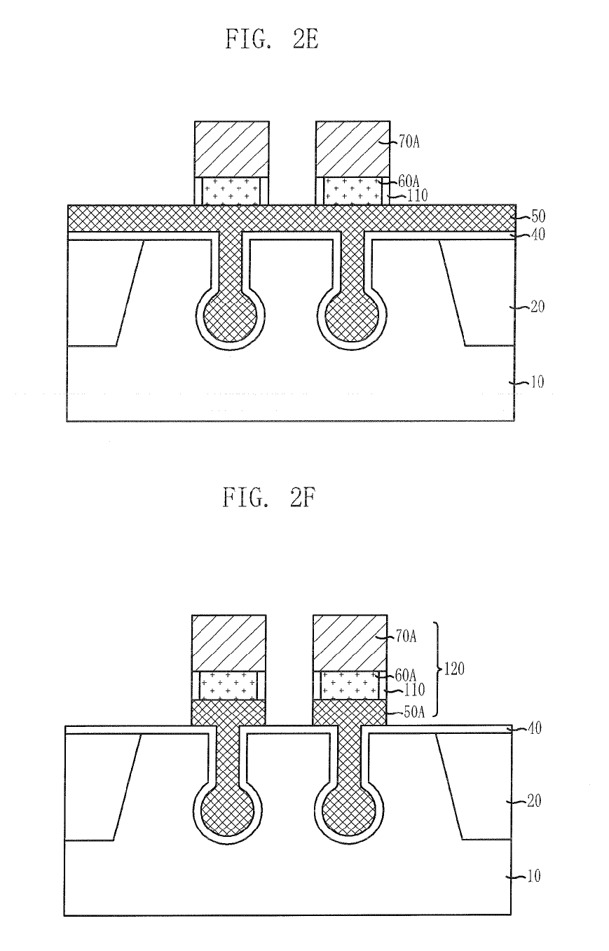

FIGS. 2A to 2F are cross-sectional views of a typical method for forming a gate electrode. In this embodiment, a transistor including a recess channel is used as an example for describing the method for fabricating a semiconductor device.

Referring to the drawings, the illustrated thickness of layers and regions are exaggerated to facilitate explanation. When a first layer is referred to as being “on” a second layer or “on” a substrate, it could mean that the first layer is formed directly on the second layer or the substrate, or it could also mean that a third layer may exist between the first layer and the second layer or the substrate. Furthermore, the same or like reference numerals throughout the various embodiments of the present invention represent the same or like elements in different drawings.

Referring to FIG. 2A, an isolation layer 20 is formed to define an active region of a substrate 10. The isolation layer 20 is formed by using a shallow trench isolation (STI) method. That is, the isolation layer 20 is formed by making a trench in the substrate 10 and then, filling the trench with a high density plasma (HDP) oxide layer.

Subsequently, a first pad layer 31 and a second pad layer 32 are sequentially formed over the substrate 10 including the isolation layer 20. The first pad layer 31 is formed with an oxide material to protect the substrate 10. The second pad layer 32 is formed with a nitride material having a high etch selectivity to the substrate 10. In another embodiment, forming the first pad layer 31 can be omitted.

Then, an organic anti-reflective coating (ARC) layer (not shown) is formed on the second pad layer 32 followed by forming a photoresist pattern (not shown) to define a subsequent first trench 33.

The first trench 33 is formed by etching portions of the first and the second pad layers 31 and 32 and the substrate 10 using the photoresist pattern.

Referring to FIG. 2B, after removing the first and the second pad layers 31 and 32, a buffer layer 34 is formed along a surface of the substrate 10 including the first trench 33. Then, a wet etch process is performed to etch the substrate 10 under a bottom portion of the first trench 33, so that a second trench 35 having a bulb shape is formed.

A standard cleaning (SC)-1 method can be used during the wet etch process. The first and the second trenches 33 and 35 comprise a trench 30 for a recess channel, which will be referred to as a gate trench 30 hereinafter. In another embodiment, the second trench 35 can be formed without removing the first and the second pad layers 31 and 32.

Referring to FIG. 2C, after the remaining portion of the buffer layer 34 is removed after the gate trench 30 is formed, a gate insulation layer 40 is formed along the surface of the substrate 10 including the gate trench 30. The gate insulation layer 40 is formed by one of a dry oxidation using an oxygen (O₂) gas at the temperature ranging from approximately 800° C. to approximately 1,100° C., a wet oxidation using a vapor atmosphere, a hydrogen chloride (HCl) oxidation using a gas mixture of an O₂ gas and an HCl gas, and an oxidation using a gas mixture of an O₂ gas and a trichloroethane (C₂H₃Cl₃) gas.

Referring to FIG. 2D, a first conductive layer 50 for a gate electrode is formed over the substrate 10 including the gate insulation layer 40. That is, the first conductive layer 50 is formed filling the gate trench 30. The first conductive layer 50 preferably is a polysilicon layer doped with impurities.

Then, a second conductive layer 60 for a gate electrode is formed over the first conductive layer 50 and a gate hard mask layer 70 is formed over the second conductive layer 60. The second conductive layer 60 is preferably a tungsten layer. Alternatively, the second conductive layer 60 may have a stack structure of a tungsten nitride (WN) layer, a tungsten silicide (WSiₓ) layer and a tungsten layer.

First and second barrier layers 80 and 90 are formed subsequently over the gate hard mask layer 70. The first barrier layer 80 is preferably an amorphous carbon (C) layer, which can provide the first barrier layer 80 with a substantially infinite etch selectivity to the underlying gate hard mask layer 70 and thereby preventing a pattern failure when forming a gate electrode pattern. The first barrier layer 80 can be also formed by using a material having a high etch selectivity ratio to the underlying gate hard mask layer 70, instead of the amorphous carbon layer.

The second barrier layer 90 may be a silicon oxy-nitride (SiON) layer. When the first barrier layer 80 is the amorphous carbon layer, a photoresist pattern 100 may not sufficiently function as an etch barrier. Thus, the second barrier layer 90 can be used as an additional etch barrier. In another embodiment, forming the second barrier layer 90 can be omitted.

After coating a photoresist layer on the second barrier layer 90, the photoresist pattern 100 is formed by a photo-exposure and a development process using a photo mask. An anti-reflective coating (ARC) layer (not shown) may be optionally formed over the second barrier layer 90 before the photoresist layer is coated.

Referring to FIG. 2E, the first and the second barrier layers 80 and 90 are etched using the photoresist pattern 100 as an etch mask. At this time, the second barrier layer 90 under the photoresist pattern 100 is etched first, and then, the first barrier layer 80 of the amorphous carbon layer is etched. It is preferable to etch the first barrier layer 80 of the amorphous carbon layer using an O₂ gas, a nitrogen (N₂) gas and an argon (Ar) gas. During etching the first barrier layer 80, a portion of the photoresist pattern 100 may be simultaneously removed.

Subsequently, the hard mask layer 70 is etched using the etched first barrier layer 80 (not shown) as an etch mask. If the hard mask layer 70 is made of a nitride layer, it is preferable to etch the hard mask layer 70 using a gas mixture of a tetrafluoromethane (CF₄) gas and an Ar gas or a gas mixture of a fluoroform (CHF₃) gas and an Ar gas. It is also preferable to etch the hard mask layer 70 with a plasma apparatus using a plasma source of an inductively coupled plasma (ICP), a capacitively coupled plasma (CCP), and an electron cyclotron resonance (ECR) type. Hereinafter, the etched hard mask layer 70 will be referred to as a hard mask pattern 70A.

Then, the first and the second barrier layers 80 and 90 and the photoresist pattern 100 over the hard mask pattern 70A are removed. The first barrier layer 80 including the amorphous carbon layer is removed in an O₂ atmosphere. The first barrier layer 80 is wet-etched by using a gas mixture of sulphuric acid (H₂SO₄) and hydrogen peroxide (H₂O₂). Besides, various etch methods, e.g., a dry etch using an O₂ gas, can be used to remove the first barrier layer 80. The gas mixture of O₂, N₂ and Ar gases are also used for the removal of the first barrier layer 80.

The second conductive layer 60 is etched subsequently by using the hard mask pattern 70A as an etch mask. The second conductive layer 60 is etched by using a fluorine (F)-based gas as an etch gas, such as sulfur hexafluoride (SF₆), nitrogen fluoride (NF₄), perfluoroethane (C₂F₆), and CF₄ gases. Although it is not shown, a portion of the first conductive layer 50 under the second conductive layer 60 can be removed together with the second conductive layer 60.

The first and the second barrier layers 80 and 90, the hard mask layer 70, and the second conductive layer 60 can be etched in the same chamber by an in-situ process or in different chambers by an ex-situ process. In another embodiment, the first and the second barrier layers 80 and 90 is not removed before etching the second conductive layer 60 so that the second conductive layer 60 can be etched using an etch mask of the hard mask pattern 70A with the first and the second barrier layers 80 and 90 remaining thereon. Hereinafter, the etched second conductive layer 60 will be referred to as a second conductive pattern 60A.

Subsequently, exposed sidewall surface of the second conductive pattern 60A is oxidized to form an oxide layer 110 as an anti-oxidation layer. The oxidation process is preferably performed in the same chamber used for etching the second conductive layer 60 by an in-situ process.

Particularly, in the oxidation process, it is preferable to generate a plasma by using only a source power and then, to perform the oxidation process by using an oxygen (O₂) gas activated by the plasma. Preferably, the oxidation process is performed by using a plasma source power ranging from approximately 100 W to approximately 600 W and by injecting a tetrafluoromethane (CF₄) gas of approximately 40 sccm to approximately 60 sccm, an O₂ gas of approximately 20 sccm to approximately 30 sccm, and a N₂ gas of approximately 900 sccm into the chamber.

Thus, a natural oxidation occurs and thus a thin oxide layer 110 is formed in the sidewall of the second conductive pattern 60A, i.e., the tungsten layer. The oxide layer 110 prevents the sidewall of the tungsten layer from being exposed, thereby preventing abnormal oxidization. A thickness of the oxide layer is preferably controlled to be in a range of approximately 40 Å to approximately 70 Å. If the oxide layer 110 is thinner than approximately 40 Å, the abnormal oxidation may not be prevented and if the oxide layer 110 is thicker than approximately 70 Å, a critical dimension (CD) of the second conductive pattern 60A overly decreases.

As shown in FIG. 2E, the oxide layer 110 is selectively formed on the sidewall of the second conductive pattern 60A. However, in another embodiment, the oxide layer 110 can be formed on a surface of the resultant structure exposed to the plasma. That is, the oxide layer 110 can be formed on an upper portion and a sidewall of the hard mask pattern 70A, the sidewall of the second conductive pattern 60A and on an exposed upper portion of the first conductive layer 50.

A cleaning process can be optionally performed using an ozone (O₃) gas to control a thickness of the oxide layer 110. Alternatively, cleaning processes using various oxide layer cleaners may be performed.

Referring to FIG. 2F, an etch process using the hard mask pattern 70A as an etch mask is performed to etch the first conductive layer 50 to form a first conductive pattern 50A. Thus, a gate electrode pattern 120 including the first and the second conductive patterns 50A and 60A, the hard mask pattern 70A and the oxide layer 110 is formed.

Impurities can be implanted into both sides of the gate electrode pattern 120 to form a source/ drain junction region subsequently.

While the present invention has been described with respect to a recess type gate electrode having an increased channel length, it can be applied to any kinds of semiconductor devices having a gate electrode including a tungsten layer and a polysilicon layer.

In accordance with the present invention, a process for forming a separate capping layer is not performed after patterning the second conductive layer of tungsten. Instead, an oxidation process is performed by using a plasma to form an anti-oxidation layer on the sidewall of the second conductive layer, preferably by an in-situ process in the same chamber where the tungsten layer is etched. Thus, it becomes possible to prevent the second conductive layer of tungsten form being abnormally oxidized through a simplified fabrication process which increases a production yield and removes problems caused by the capping layer.

While the present invention has been described with respect to the specific embodiments, it will be apparent to those skilled in the art that various changes and modifications may be made without departing from the spirit and scope of the invention as defined in the following claims.

What is claimed is:

1. A method for forming a gate electrode in a semiconductor device, the method comprising:
providing a substrate;
forming a gate insulation layer over the substrate;
forming a first conductive layer over the gate insulation layer and a second conductive layer on the first conductive layer;
forming a hard mask pattern over the second conductive layer;
etching the second conductive layer using the hard mask pattern as an etch mask;
performing an oxidation process to form an anti-oxidation layer on a sidewall of the etched second conductive layer; and
etching the first conductive layer using the hard mask as an etch mask.

2. The method of claim 1, wherein the second conductive layer is a single tungsten (W) layer or a stack structure of a tungsten nitride (WN) layer, a tungsten silicide layer (WSiₓ) layer, and a tungsten layer.

3. The method of claim 1, wherein the oxidation process is performed in a plasma chamber.

4. The method of claim 3, wherein the oxidation process is performed by using a tetrafluoromethane (CF₄) gas of approximately 40 sccm to approximately 60 sccm, an oxygen (O₂) gas of approximately 20 sccm to approximately 30 sccm, and a nitrogen (N₂) gas of approximately 100 sccm to approximately 900 sccm.

5. The method of claim 3, wherein the oxidation process is performed by only applying a source power to the plasma chamber.

6. The method of claim 1, wherein the anti-oxidation layer is a plasma oxide.

7. The method of claim 6, wherein the anti-oxidation layer has a thickness ranging from approximately 40 Åto approximately 70 Å.

8. The method of claim 1, further comprising performing a cleaning process using ozone (O₃) gas after the oxidation process.

9. The method of claim 1, wherein etching the second conductive layer and the oxidation process are performed in the same chamber by an in-situ process.

10. The method of claim 1, wherein forming the hard mask pattern, etching the second conductive layer, performing the oxidation process and etching the first conductive layer are performed in the same chamber by an in-situ process or in different chambers by an ex-situ process.
